(19) United States
(12) Patent Application Publication
(10) Pub. No.: US 2023/0387119 A1
(43) Pub. Date: Nov. 30, 2023

(54) SEMICONDUCTOR DEVICE OF THE SILICON ON INSULATOR TYPE AND CORRESPONDING MANUFACTURING METHOD

(71) Applicant: STMicroelectronics (Crolles 2) SAS, Crolles (FR)

(72) Inventors: Olivier Weber, Grenoble (FR); Franck Arnaud, St Nazaire Les Eymes (FR)

(21) Appl. No.: 18/324,327

(22) Filed: May 26, 2023

(30) Foreign Application Priority Data
May 30, 2022 (FR) 2205119

(51) Int. Cl. H01L 27/092; H01L 27/12; H01L 29/06; H01L 29/786; H01L 21/8238

(52) U.S. Cl. CPC H01L 27/0922; H01L 27/0928; H01L 27/1203; H01L 29/0649; H01L 29/78696; H01L 21/823807; H01L 21/823842; H01L 21/823892

(57) ABSTRACT

The semiconductor device of a silicon on insulator type includes a NMOS transistor in a P-type well of the carrier substrate, a PMOS transistor in an N-type well of the carrier substrate, and a power supply circuit configured to generate voltages in the P-type and N-type wells, so as to selectively provide neutral, forward and reverse back bias conditions to the NMOS transistor and the PMOS transistor. The neutral back bias condition is achieved when a first non-zero negative voltage is applied to the P-type well and a first non-zero positive voltage is applied to the N-type well. The NMOS and PMOS transistors are configured to have nominal threshold voltages in the neutral back bias condition.

### CROSS-REFERENCE TO RELATED APPLICATIONS

This application claims the priority benefit of French Patent Application No. 2205119, filed on May 30, 2022, which is hereby incorporated by reference to the maximum extent allowable bylaw.

### TECHNICAL FIELD

Embodiments and implementations relate to the semiconductor devices of the silicon on insulator type and a corresponding method.

### BACKGROUND

The SOI substrates allow in particular benefiting from a “back bias”, that is to say a field effect in the semiconductor film through the buried dielectric layer, caused by a bias of the carrier substrate. In practice, it is a doped well located in the carrier substrate which is locally biased. The channel regions of MOS transistors (acronym for “Metal Oxide Semiconductor”) produced in SOI technology are located in the semiconductor film, such that the back bias allows changing the behavior of the MOS transistors.

Typically, a back bias of negative sign for a PMOS transistor and of positive sign for an NMOS transistor, called forward back bias, allows lowering the threshold voltage of the transistors and thus improving their performance, but increases the current leakage; while a back bias of positive sign for a PMOS transistor and of negative sign for an NMOS transistor, called reverse back bias, allows increasing the threshold voltage of the transistors and thus reducing the current leakage, but deteriorates their performance.

Furthermore, the PMOS and NMOS transistors are typically produced in wells of the carrier substrate having a respective doping type, or in a configuration of “regular wells” in which the PMOS transistors are produced in an N-type well and the NMOS transistors in a P-type well (that is to say in the manner of the productions of MOS transistor in monolithic substrate, “bulk”); either in a configuration of “flip wells” in which the PMOS transistors are made in a P-type well and the NMOS transistors in an N-type well (which is possible due to the buried dielectric layer of SOI substrates).

Consequently, in case of back bias, the potential difference between the P-type and N-type wells is limited by the threshold voltage of the PN junction formed between the wells, such that the configuration of normal wells does not allow (or too little to be usable) the forward back bias, and the flip wells configuration does not allow (or too little to be usable) the reverse back bias.

The cointegration of normal wells with flip wells is not advantageous, in particular in terms of surface occupation, because in this case, transistors of the same type (NMOS or PMOS) must be produced in separate wells and electrically isolated.

Techniques for electrically isolating N-type and P-type casings using additional lateral isolation trenches and which are deeper than typical lateral isolation trenches, allow both forward and reverse back biases, but generate additional manufacturing steps, which are expensive and complex in terms of manufacturing the semiconductor device, and also generate an additional complexity in terms of circuit design.

Embodiments and implementations allow forward and reverse back biases that can be used at values which are greater than the threshold voltage of the PN junction between the wells, both for NMOS transistors and PMOS transistors, the transistors of the same type (NMOS or PMOS) being all capable of being co-integrated in the same well of the carrier substrate, and without generating complexities in the manufacture and in the design of the circuit.

### SUMMARY

According to one aspect, a semiconductor device of the silicon on insulator type is proposed in this regard, including at least one NMOS transistor in and on a semiconductor film separated from a P-type doped well arranged in a carrier substrate by a buried dielectric layer, at least one PMOS transistor in and on a semiconductor film separated from an N-type doped well arranged in the carrier substrate by the buried dielectric layer, and a power supply circuit configured to generate voltages in the P-type and N-type wells, so as to selectively provide neutral, forward and reverse back bias conditions to the NMOS transistor and to the PMOS transistor, in which the power supply circuit is configured to generate, in the neutral back bias condition, a first non-zero negative voltage in the P-type well and a first non-zero positive voltage in the N-type well, the NMOS and PMOS transistors being respectively configured to have nominal threshold voltages in the neutral back bias condition.

In other words, it is proposed to produce the NMOS and PMOS transistors which are specifically configured to have nominal threshold voltages, that is to say the threshold voltages provided for a normal operation of the circuit, in the particular condition of neutral back bias where the wells of the transistors are respectively negatively and positively biased.

Consequently, from the neutral back bias condition comprising a negative bias of the P-type well and a positive bias of the N-type well, it is possible to increase the voltage biasing the P-type well and simultaneously decrease the voltage biasing the N-type well, so as to produce a usable forward back bias, both for the NMOS and PMOS transistors, without exceeding the threshold voltage of the PN junction between the two wells.

Embodiments and implementations relate to the semiconductor devices of the silicon on insulator type, usually designated by the acronym “SOI”, that is to say semiconductor devices made from a substrate of the SOI type including a carrier substrate, a buried dielectric layer, and a semiconductor film typically made of silicon which can be in a fully depleted state of minority carriers (“FDSOI” for “Fully Depleted SOI”).

According to one embodiment, the power supply circuit is, in this regard, configured to generate, in the forward back bias condition, a voltage which is higher than the first non-zero negative voltage in the P-type well and a voltage which is lower than the first non-zero positive voltage in the N-type well.

According to one embodiment, the power supply circuit is configured to generate, in the reverse back bias condition, a voltage which is lower than the first non-zero negative voltage in the P-type well and a voltage which is higher than the first non-zero positive voltage in the N-type well.

Indeed, from the same neutral back bias condition comprising a negative bias of the P-type well and a positive bias of the N-type well, it is also possible to decrease the voltage biasing the P-type well and simultaneously increase the voltage biasing the N-type well, so as to produce a usable reverse back bias, both for the NMOS and PMOS transistors, without exceeding the threshold voltage of the PN junction between the two wells.

According to one embodiment, the at least one NMOS transistor includes a tensile strained channel region, in the respective semiconductor film, and the at least one PMOS transistor includes a compressively strained channel region, in the respective semiconductor film.

A mechanical tensile strain in one direction of a silicon crystal typically generates a compressive strain in a perpendicular direction of the material, and vice versa. The term “a tensile/compressively strained channel region” means that the given strain (tension or compression) is considered in the direction of the channel region, that is to say in the direction between the source and the drain of the transistor.

Tensile strains in the channel of an NMOS transistor and compressive strains in the channel of a PMOS transistor allow improving the performance of the transistors, in particular in terms of carrier mobility. Nevertheless, conventionally the use of the mechanical strains in the channels of the transistors has difficulties insofar as they generate a reduction in the threshold voltage of the transistor and thus an increase in the current leakage. However, the negative bias of the P-type well and the positive bias of the N-type well generate an increase in the threshold voltages of the respective transistors, thus allowing benefiting from the advantages of the mechanical strains in the channels of the transistors without undergoing the drawbacks thereof.

According to one embodiment, the at least one PMOS transistor includes a channel region made of silicon-germanium alloy, in the respective semiconductor film, with a germanium concentration greater than 25% atomic percent.

Similarly, the use of a channel region made of a silicon-germanium compound with a high dose of germanium, allows improving the performance of PMOS transistors, but in return generates a reduction in the threshold voltage of the transistor. Herein again, the positive bias of the N-type well generates an increase in the threshold voltage of the PMOS transistors, thus allowing benefiting from the advantages of the silicon-germanium composition in the channels without undergoing the drawbacks thereof.

According to one embodiment, the NMOS and PMOS transistors include a gate dielectric layer located between, respectively, a gate conductive region and the semiconductor film, the gate dielectric layer comprising nitrogen so as to form a silicon oxynitride “SiON” layer.

The presence of nitrogen in silicon oxide allows increasing the capacitance of the gate dielectric layer without reducing the physical thickness of the gate dielectric layer, which is advantageous in terms of performance, while maintaining tunneling leakage constant through the gate dielectric layer. However, the presence of nitrogen in the gate dielectric layer generates in return a reduction of the threshold voltage of the NMOS transistors and an increase in the threshold voltage of the PMOS transistors. However, given the particular configuration of the NMOS and PMOS transistors to have nominal threshold voltages in the particular neutral back bias condition where the wells of the transistors are respectively negatively and positively biased, it is herein again possible to benefit from the advantages of the silicon oxynitride in the gate dielectric layer without undergoing the drawbacks thereof.

According to one embodiment, the NMOS and PMOS transistors include a gate conductive region including titanium nitride and a titanium nitride additive selected from lanthanum and aluminum, so as to modulate the work function of the gate to obtain the nominal threshold voltages in the neutral back bias condition.

Lanthanum and aluminum allow increasing or decreasing the threshold voltage of the PMOS and NMOS transistors, and thus advantageously allows adjusting the threshold voltages to a nominal value suitable for normal use of the circuit in the aforementioned neutral back bias condition.

According to one embodiment, the NMOS and PMOS transistors include a respective channel region including a concentration of doping species which are adapted to modulate the work function of the channel region so as to obtain the nominal threshold voltages in the neutral back bias condition.

The doping of the channel region, which can nevertheless remain intrinsic, that is to say include a zero concentration of doping species, herein again allow adjusting the threshold voltage of the PMOS and NMOS transistors to a nominal value adapted to the normal use of the circuit in the aforementioned neutral back bias condition.

According to one embodiment, the device includes at least one CMOS circuit provided with the NMOS transistors and the PMOS transistor, the NMOS and PMOS transistors being configured to have nominal threshold voltages in the neutral back bias condition, in at least one of the following intervals:
an interval of threshold voltages called super low threshold voltages comprised between 0.15 V and 0.25 V, in absolute values;
an interval of threshold voltages called low threshold voltages comprised between 0.2 V and 0.3 V, in absolute values;
an interval of threshold voltages called lower median threshold voltages comprised between 0.25 V and 0.35 V, in absolute values;
an interval of threshold voltages called upper median threshold voltages comprised between 0.3 V and 0.4 V, in absolute values; or
an interval of threshold voltages called high threshold voltages comprised between 0.35 V and 0.45 V, in absolute values.

In particular, the device could include at least one CMOS circuit in respectively two of the intervals of the list above, or at least one CMOS circuit in respectively three of the intervals of the list above, or at least one CMOS circuit in respectively four of the intervals of the list above, or at least one CMOS circuit in each interval of the list above.

According to another aspect, it is proposed a method for manufacturing a semiconductor device of the silicon on insulator type comprising:
a formation of at least one NMOS transistor in and on a semiconductor film separated from a P-type doped well arranged in a carrier substrate by a buried dielectric layer,
a formation of at least one PMOS transistor in and on a semiconductor film separated from an N-type doped well arranged in the carrier substrate by the buried dielectric layer, and
a formation of a power supply circuit capable of generating voltages in the P-type and N-type wells, so as to selectively provide neutral, forward and reverse back bias condition, to the NMOS transistor and to the PMOS transistor, the neutral back bias condition comprising a first non-zero negative voltage applied in the P-type well and a first non-zero positive voltage applied in the N-type well,
the formations of the NMOS and PMOS transistors being configured to provide the NMOS and PMOS transistors with respective nominal threshold voltages in the neutral back bias condition.

According to one implementation, the forward back bias condition comprises a voltage which is higher than the first non-zero negative voltage applied in the P-type well and a voltage which is lower than the first non-zero positive voltage applied in the N-type well.

According to one implementation, the reverse back bias condition comprises a voltage which is lower than the first non-zero negative voltage applied in the P-type well and a voltage which is higher than the first non-zero positive voltage applied in the N-type well.

According to one implementation, the formation of the at least one NMOS transistor comprises forming a tensile strained channel region, in the respective semiconductor film, and the formation of the at least one PMOS transistor includes a formation of a compressively strained channel region in the respective semiconductor film.

According to one implementation, the formation of the at least one PMOS transistor includes the formation of a channel region made of silicon-germanium alloy in the respective semiconductor film, with a germanium concentration which is greater than 25% atomic percent.

According to one implementation, the formations of the NMOS and PMOS transistors include a formation of a gate dielectric layer located between, respectively, a gate conductive region and the semiconductor film, the gate dielectric layer comprising nitrogen so as to form a silicon oxynitride layer.

According to one implementation, the formations of the NMOS and PMOS transistors include a formation of a gate conductive region including titanium nitride and a titanium nitride additive selected from lanthanum and aluminum, so as to modulate the work function of the gate to obtain the nominal threshold voltages in the neutral back bias condition.

According to one implementation, the formations of the NMOS and PMOS transistors include a formation of a respective channel region including a concentration of doping species suitably modulating the work function of the channel region to obtain the nominal threshold voltages in the neutral back bias condition.

According to one implementation, the method includes a formation of at least one CMOS circuit provided with the NMOS transistors and the PMOS transistor, configured to provide the NMOS and PMOS transistors with nominal threshold voltages in the neutral back bias condition, in at least one of the following intervals:
an interval of threshold voltages called super low threshold voltages comprised between 0.15 V and 0.25 V, in absolute values;
an interval of threshold voltages called low threshold voltages comprised between 0.2 V and 0.3 V, in absolute values;
an interval of threshold voltages called lower median threshold voltages comprised between 0.25 V and 0.35 V, in absolute values;
an interval of threshold voltages called upper median threshold voltages comprised between 0.3 V and 0.4 V, in absolute values; or
an interval of threshold voltages called high threshold voltages comprised between 0.35 V and 0.45 V, in absolute values.

### BRIEF DESCRIPTION OF THE DRAWINGS

Other advantages and features of the invention will appear on examining the detailed description of embodiments and implementations, without limitation, and of the appended drawings, in which:

FIG. 1 illustrates an exemplary embodiment of a semiconductor device;

FIG. 2 show a diagram illustrating various bias condition relating to the semiconductor device of FIG. 1;

FIG. 3 illustrates a graph of the possible applications for implementing neutral, forward, and reverse back bias conditions;

FIG. 4 illustrates cross sectional diagram of semiconductor devices according to embodiments;

FIG. 5 illustrates a graph of pairs of threshold voltages for the respective CMOS circuits;

FIG. 6 illustrates steps of a method for manufacturing NMOS transistors according to an embodiment; and

FIG. 7 illustrates steps of a method for manufacturing PMOS transistors according to an embodiment.

### DETAILED DESCRIPTION OF ILLUSTRATIVE EMBODIMENTS

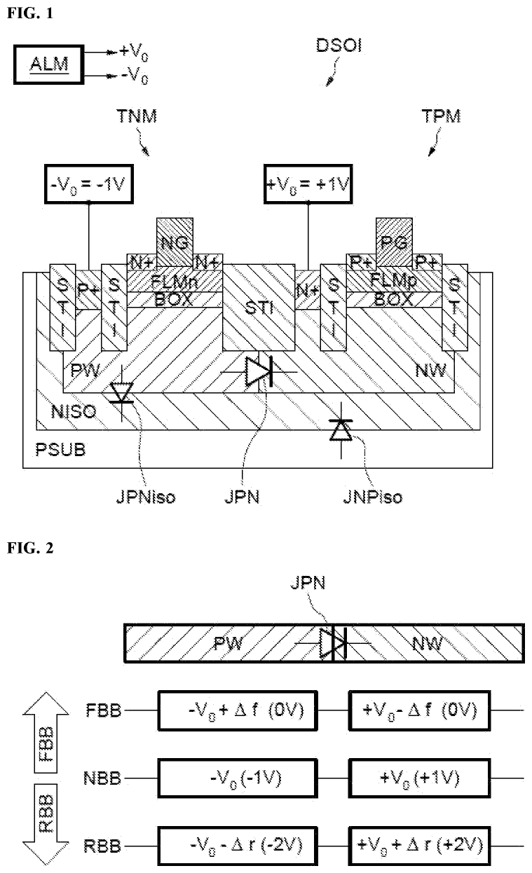

FIG. 1 illustrates an exemplary embodiment of a semiconductor device DSOI of the silicon on insulator type comprising at least one NMOS (acronym well known to the person skilled in the art for the terms “N-type Metal Oxide Semiconductor”) transistor TNM and at least one PMOS (acronym well known to the person skilled in the art of the terms “P-type Metal Oxide Semiconductor”) transistor TPM.

In silicon on insulator type technologies, the active region of MOS transistors is located in a semiconductor film located on a buried dielectric, isolating the semiconductor film from a carrier substrate. The MOS transistors are thus formed in and on the semiconductor film, that is to say in particular that the conduction regions (the source and the drain) are implanted in the semiconductor film, and that their control regions (the gate) are formed on the open surface, called front face, of the semiconductor film.

The NMOS transistor TNM is produced in and on a semiconductor film FLMn which is separated from a P-type doped well PW by the buried dielectric layer BOX, the well PW being arranged in the carrier substrate PSUB.

The PMOS transistor TPM is produced in and on a semiconductor film FLMp which is separated from an N-type doped well NW by the buried dielectric layer BOX, the well NW being arranged in the carrier substrate PSUB.

Advantageously, from the point of view of the mobility of the carriers in the channel regions of the transistors TNM, TPM, the semiconductor film FLMn of the NMOS transistor can be tensile strained in the direction of the channel region of the NMOS transistor.

The tensile strain can be obtained by means of conventional techniques, for example with a tensile nitride layer encapsulating the gate; or by using a pre-strained SOI substrate; or by locally introducing a tensile strain in the channel by other techniques, such as the “BOX creep” (use of a temperature rise of a sacrificial layer having a coefficient of thermal expansion different from that of the channel region), or “STRASS” (acronym of the terms “Strain by Top Recrystallization of Amorphized SiGe on SOI”, strain formation by surface recrystallization of an amorphous material).

The channel region of the NMOS transistor is suitable to be formed in the region of the semiconductor film FLMn between the N+ conduction terminals of the NMOS transistor, under the gate region NG.

Moreover, the semiconductor film FLMn can be formed in intrinsic silicon, or in P-type doped silicon with a greater or lesser concentration of doping species.

Similarly, the semiconductor film FLMp of the PMOS transistor can advantageously be compressively strained in the direction of the channel region of the PMOS transistor, the channel region of the PMOS transistor being adapted to be formed in the region of the semiconductor film FLMp between the P+ conduction terminals of the PMOS transistor, under the gate region PG. The semiconductor film FLMp can advantageously be formed from a composition of silicon-germanium SiGe30%, with a germanium concentration which is greater than 25% atomic percent, for example 30%, which can itself also be intrinsic or N-type doped to greater or lesser concentration of doping species.

The gate regions NG, PG of the transistors TNM, TPM typically include a conductive layer and a gate dielectric layer located between, respectively, the conductive layer and the semiconductor film FLMn, FLMp. Typically, the conductive layer includes a portion made of metal or a metal compound, for example titanium nitride, located on the side of the channel region for example on the gate dielectric layer, and a portion made of polycrystalline silicon used to electrically contact the gate.

Advantageously, the gate dielectric layer comprises a layer of silicon oxynitride (“SiON”, or SiOₓN_{y}, for example Si₂O₂N with x=1, y=0.5), for example in a two-layer structure comprising a high-permittivity (usually “high-k”) dielectric layer, such as hafnium oxide HfO₂, and the silicon oxynitride SiON layer. The presence of silicon oxynitride allows increasing the capacitance of the gate dielectric region and thus improving the performance of the transistor, relative to a conventional silicon dioxide layer. Indeed, a greater capacitance of the gate dielectric generates an increase in the number of carriers in the channel for a given voltage, which allows conduction of a greater amount of current. The concentration of nitrogen in silicon oxynitride SiON also allows modulating the threshold voltage of NMOS and PMOS transistors.

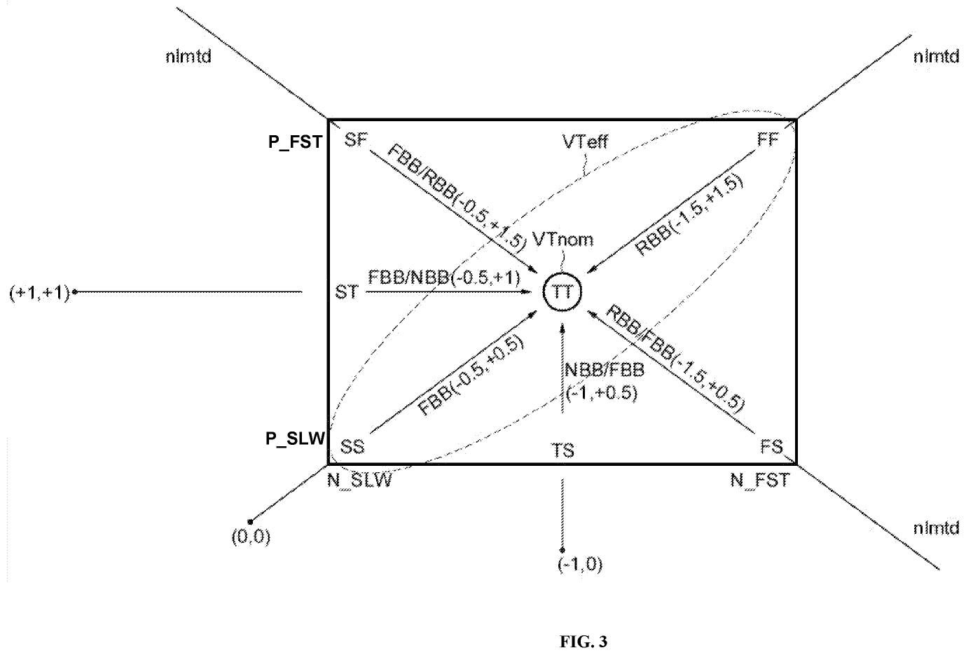

The different characteristics of the NMOS and PMOS transistors described above are provided, on the one hand, in order to configure the NMOS and PMOS transistors to have respective nominal threshold voltages VTnom (FIG. 3) in the neutral back bias NBB condition (FIG. 2) described below; and, on the other hand, simultaneously in order to benefit from the aforementioned techniques for improving the performance of NMOS and PMOS transistors.

The semiconductor device DSOI indeed includes a power supply circuit ALM configured to generate voltages +V₀, −V₀ in the P-type well PW and the N-type well NW, so as to selectively provide neutral NBB, forward FBB and reverse RBB back bias conditions (FIG. 2) to the NMOS transistor and the PMOS transistor.

The neutral back bias NBB condition is characterized by a generation of a first non-zero negative voltage −V₀, for example substantially −1 V (volt), in the P-type well PW housing the NMOS transistor; as well as a first non-zero positive voltage +V₀, for example substantially +1 V, in the N-type well NW housing the PMOS transistor.

In this regard, the P-type well PW includes a P+ contact region capable of receiving the first negative voltage −V₀ and the N-type well NW includes an N+ contact region capable of receiving the first positive voltage +V₀. The device DSOI can further include an N-type isolation well NISO, preventing the bias of the carrier substrate PSUB at the −V₀ or +V₀ voltages applied in the wells PW or NW, due to the two opposite PN junctions, JPNiso and JNPiso. Lateral isolation structures STI, for example shallow isolation trenches, are typically provided to provide a local electrical isolation between the elements of the wells PW, NW, and in particular to form access to the respective wells PW, NW by the P+, N+ contact.

Thus, given that the NMOS and PMOS transistors are specifically configured to have a nominal threshold voltage, and therefore a nominal behavior, in the neutral back bias condition “−V₀; +V₀” (that is to say the threshold voltages and behavior provided for a normal operation of the circuit), it is advantageously possible to produce usable forward FBB and reverse RBB back biases, both for NMOS transistors and PMOS, without exceeding the threshold voltage of the PN junction between the two wells.

Reference is made, in this regard, to FIG. 2, which illustrates the neutral back bias NBB condition, the forward back bias FBB condition and the reverse back bias RBB condition, in the wells PW, NW of the semiconductor device DSOI described in relation to FIG. 1.

It is recalled that the power supply circuit ALM is configured to generate a first non-zero negative voltage −V₀, for example substantially −1 V or even −1.5 V, in the well PW housing the NMOS transistor, as well as a first non-zero positive voltage +V₀, for example substantially +1 V or even +1.5 V, in the well NW housing the PMOS transistor, under the neutral back bias NBB condition.

In the neutral back bias NBB condition, the JPN junction (and the JPNiso junction) between the wells PW and NW (respectively NISO) is biased to a forward voltage of −2 V or even −3 V and is therefore blocked. Similarly, the JNPiso junction between the well NISO and the substrate PSUB is biased to a forward voltage of −1 V or even −1.5 V (considering that the potential of the carrier substrate PSUB is at 0 V), and is therefore blocked.

The power supply circuit ALM is further configured to generate, in the forward back bias FBB condition, a voltage −V₀+Δf which is greater than the first non-zero negative voltage −V₀ in the well PW, for example a voltage of substantially 0 V, that is to say greater “+Δf” by substantially +1 V or even +1.5 V; as well as a voltage +V₀−Δf which is lower than the first non-zero positive voltage +V₀ in the well NW, for example a voltage of substantially 0 V, that is to say lower “−Δf” by substantially −1 V or even −1.5 V.

In the forward back bias FBB condition, the JPN, JPNiso, JNPiso junctions between the wells PW, NW, NISO, PSUB are biased to forward voltages of 0 V and are therefore blocked.

The power supply circuit ALM is further configured to generate, in the reverse back bias RBB condition, a voltage −V₀−Δr which is lower than the first non-zero negative voltage −V₀ in the well PW, for example a voltage of substantially −2 V or even −3 V, that is to say lower “−Δr” by substantially −1 V or −1.5 V; and a voltage +V₀+Δr which is greater than the first non-zero positive voltage +V₀ in the well NW, for example a voltage of substantially +2 V or even +3 V, that is to say greater than “+Δr” by substantially +1 V or even +1.5 V.

In the reverse back bias RBB condition, the JPN junction (and the JPNiso junction) between the wells PW and NW (respectively between the wells PW and NISO) is biased to a forward voltage of −4 V or even −6 V and is therefore blocked. Similarly, the JNPiso junction between the well NISO and the substrate PSUB is biased to a forward voltage of −2 V or even −3 V (considering that the potential of the carrier substrate PSUB is at 0 V), and is therefore blocked.

FIG. 3 illustrates a graph of the possible applications for implementing neutral, forward, and reverse back bias conditions.

Indeed, the back bias conditions can advantageously allow compensating for a random drift of the effective threshold voltages of the NMOS and PMOS transistors, typically due to the physical hazards of the manufacturing methods.

Thus, the horizontal axis of the graph represents the random variations of the characteristics of the NMOS transistors, going from left to right of a “slow” behavior N_SLW, that is to say a larger threshold voltage (in absolute value), towards a “fast” behavior N_FST, that is to say a smaller threshold voltage (in absolute value).

The vertical axis of the graph represents the random variations of the characteristics of the PMOS transistors, going from bottom to top of a “slow” behavior P_SLW, that is to say a larger threshold voltage (in absolute value), towards a “fast” behavior P_FST, that is to say a smaller threshold voltage (in absolute value).

The coordinates of significant points are represented on the graph, SS, TS, FS, TT, ST, SF, FF, the left letter of the coordinates meaning the behavior of the NMOS transistor, the right letter meaning the behavior of the PMOS transistor, with “S” for a “slow” behavior, “T” for a “normal” behavior and “F” for a “fast” behavior.

The ellipse VTeff in the diagonal SS, TT, FF represents the dispersion in practice of the threshold voltages of a statistical population of pairs of NMOS and PMOS transistors.

Thus, in the most common symmetrical case, that is to say when the PMOS and NMOS transistors have a drift in the same direction, substantially along the diagonal SS, TT, FF, a forward back bias FBB or a reverse back bias RBB, will allow bringing the effective threshold values back to the nominal value VTnom, towards the point TT.

In the symmetrical case, the forward FBB or reverse RBB back biases are applied in the two wells PW, NW as represented in FIG. 2, with variations “+/−Δr”, “+/−Δf” whose amplitude corresponds to the difference between the effective threshold voltage SS, FF and the nominal threshold voltage Vnom, at the point TT, for example (V₀+0.5V; V₀−0.5V) and (V₀−0.5V; V₀+0.5V).

Nevertheless, the semiconductor device DSOI which is previously described in relation to FIG. 1 further allows compensating for an asymmetrical drift of the NMOS and PMOS transistor characteristics, that is to say when the PMOS and NMOS transistors have different or opposite drifts.

Indeed, in this regard, it is possible, for example, to provide a forward back bias to one of the two wells PW, NW and a reverse back bias to the other of the two wells NW, PW.

For example, it will be possible to provide a forward back bias to the well PW and a reverse back bias to the well NW, “FBB/RBB” in order to compensate for the drift of the SF case, with variations “+Δf”, “+Δr” in suitable amplitude, for example (V₀+0.5V; V₀+0.5V). Conversely, it will be possible to provide a reverse back bias to the well PW and a forward back bias to the well NW, “RBB/FBB” in order to compensate for the drift of the FS case, with variations “−Δr”, “−Δf” in suitable amplitude, for example (V₀−0.5V; V₀−0.5V).

Furthermore, it is also possible, for example, to provide a forward or reverse back bias to one of the two wells PW, NW and the neutral back bias to the other of the two wells NW, PW.

For example, it will be possible to provide a forward back bias to the well PW and a neutral back bias to the well NW, “FBB/NBB” in order to compensate for the drift of the ST case, with a variation “+Δf” in suitable amplitude, for example (V₀+0.5V; V₀). Conversely, it will be possible to provide a reverse back bias to the well PW and a neutral back bias to the well NW, “NBB/FBB” in order to compensate for the drift of the TS case, with a variation “−Δf” in suitable amplitude (for example V₀; V₀−0.5V).

In fact, all cases of drift can be compensated with suitable amplitude variations. Nevertheless, in particular the forward back bias FBB is limited to substantially (0V, 0V) because of the PN junction threshold between the wells PW, NW. On the other hand and in particular, the reverse back bias RBB in the two wells PW, NW and the asymmetrical back biases FBB/RBB and RBB/FBB are not amplitude limited nlmtd (to a lesser extent than the reverse breakdown voltage PN junctions).

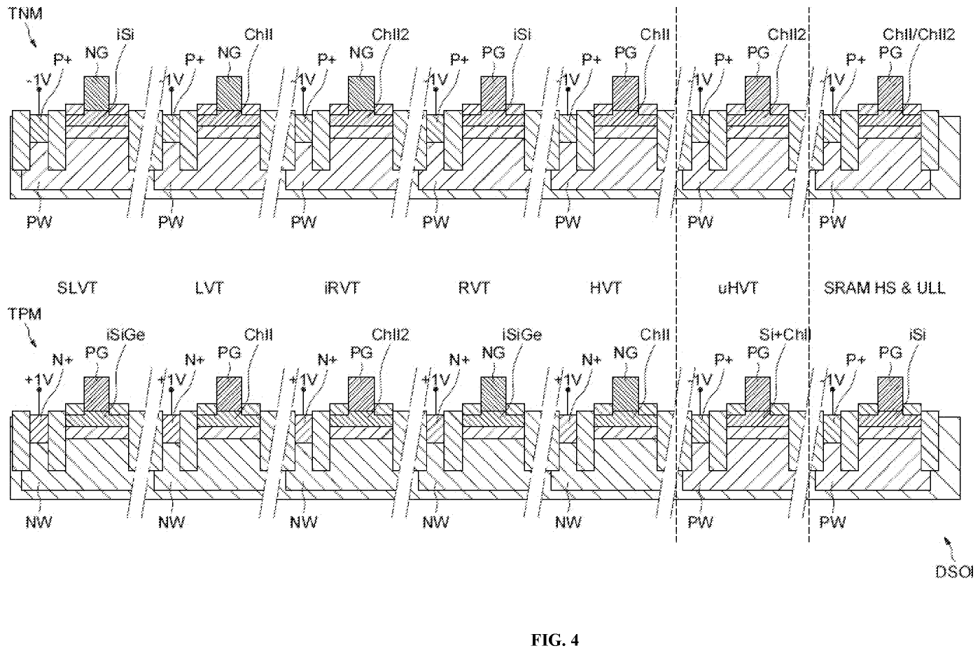

FIG. 4 illustrates examples of advantageous embodiments of the semiconductor device DSOI, including CMOS (acronym well known to the person skilled in the art of the terms “Complementary Metal Oxide Semiconductor”) circuits each provided with at least one NMOS transistor TNM and at least one PMOS transistor TPM as previously described in relation to FIGS. 1 to 3.

In these examples, the NMOS transistors and the PMOS transistors can advantageously be configured to have respective nominal threshold voltages at different values under the neutral back bias NBB condition, for each respective CMOS circuit SLVT, LVT, iRVT, RVT, HVT.

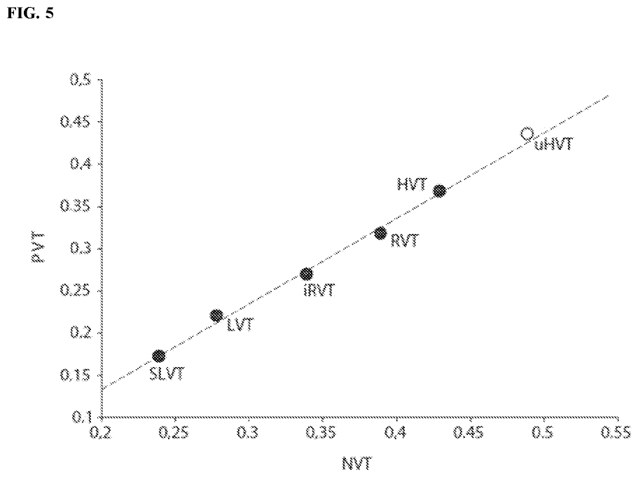

FIG. 5 illustrates a graph of the pairs of threshold voltages for the respective CMOS circuits SLVT, LVT, iRVT, RVT, HVT.

The NMOS and PMOS transistors can be configured to have threshold voltages in an interval of threshold voltages called super low threshold voltages SLVT, between 0.15 V and 0.25 V, in absolute values, for example 0.24 V for the NMOS transistor and 0.17 V for the PMOS transistor.

The NMOS and PMOS transistors can be configured to have threshold voltages in an interval of threshold voltages called low threshold voltages LVT, between 0.2 V and 0.3 V, in absolute values, for example 0.28 V for the NMOS transistor and 0.22 V for the PMOS transistor.

The NMOS and PMOS transistors can be configured to have threshold voltages in an interval of threshold voltages called lower median threshold voltages iRVT, between 0.25 V and 0.35 V, in absolute values, for example 0.34 V for the NMOS transistor and 0.27 V for the PMOS transistor.

The NMOS and PMOS transistors can be configured to have threshold voltages in an interval of threshold voltages called upper median threshold voltages RVT, between 0.3 V and 0.4 V, in absolute values, for example 0.39 V for the NMOS transistor and 0.32 V for the PMOS transistor.

The NMOS and PMOS transistors can be configured to have threshold voltages in an interval of threshold voltages called high threshold voltages HVT, between 0.35 V and 0.45 V, in absolute values, for example 0.43 V for the NMOS transistor and 0.37V for the PMOS transistor.

All threshold voltage values presented above in relation to FIG. 5, are given by way of example, and can be considered to within 10%.

Reference is made again to FIG. 4.

On the one hand, the different threshold voltages SLVT, LVT, iRVT, RVT, HVT of the transistors of the CMOS circuits can be parameterized by modulating the work function of the gate regions NG, PG, in particular by introducing an additive into the metal portion, made of titanium nitride, of the grid. For example, lanthanum is an additive allowing lowering the work function of the grid NG, in this case called “N-type work function” without designating a doping type. For example, aluminum is an additive allowing increasing the work function of the gate PG, in this case called “P-type work function” without designating a doping type.

On the other hand, the different threshold voltages SLVT, LVT, iRVT, RVT, HVT of the transistors of the CMOS circuits can be parameterized by modulating the work function of the channel regions, in particular by doping the respective semiconductor films FLMn, FLMp, at a concentration of doping species which can be zero iSi, iSiGe (intrinsic semiconductor material) or at different concentrations ChII, ChII2 (for example two concentration levels of the dopants).

Moreover, all NMOS transistors of the CMOS circuits of the semiconductor device DSOI can be made in the same P-type well PW, and biased according to the same neutral (−1V) or forward or reverse back bias condition. Similarly, all PMOS transistors of the CMOS circuits of the semiconductor device DSOI can be produced in the same N-type well NW, and biased according to the same neutral (+1V) or forward or reverse back bias condition.

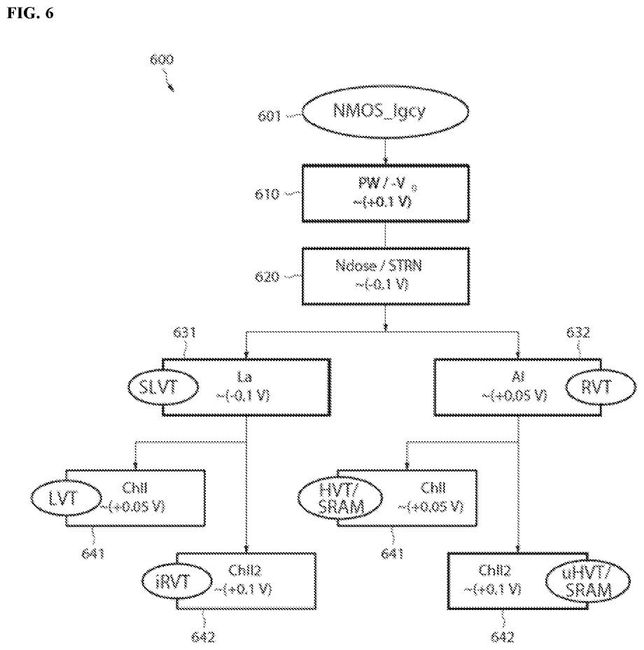

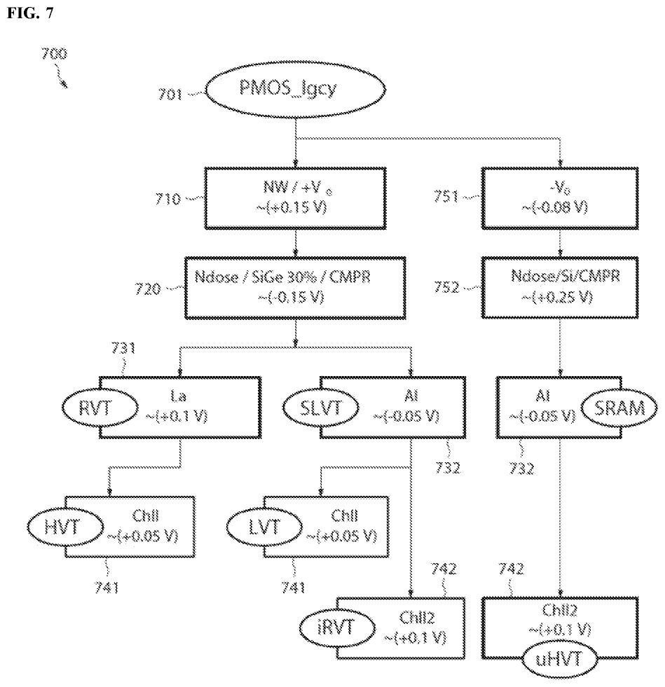

Furthermore, the semiconductor device DSOI can advantageously include a CMOS circuit with ultra-low leakage uHVT (also called “with ultra-high threshold voltages”), and a CMOS circuit of static random access memory “SRAM” cells, according to the same manufacturing method steps as the other CMOS circuits (reference will be made in this regard to FIGS. 6 and 7 described below). The two NMOS and PMOS types of the uHVT and SRAM transistors are located in a P-type doped semiconductor well PW, arranged in the carrier substrate PSUB. Consequently, the uHVT, SRAM transistors, in particular PMOS transistors, are not adapted to being made in the same well PW, NW as the transistors of the same type of the CMOS circuits.

FIG. 6 illustrates steps of a manufacturing method 600 of the NMOS transistors previously described in relation to FIGS. 4 and 5. More particularly, the steps 610, 620, 631, 632, 641, 642 of FIG. 6 represent the modifications made to a manufacture of a conventional NMOS transistor NMOS_lgcy to obtain the transistors TNM which are previously described in relation to FIGS. 4 and 5, that is to say the NMOS transistors configured to have the different nominal threshold voltages SLVT, LVT, iRVT, RVT, HVT in the neutral back bias NBB condition.

The conventional transistor NMOS_lgcy, considered as a starting point in step 601, is produced in an N-type well arranged in the carrier substrate, includes an intrinsic silicon channel region, and has for example a threshold voltage of substantially 0.34V. All structural characteristics of the conventional transistor NMOS_lgcy which are not modified in the method 600, such as in particular the channel length, the implantations of the N+ conduction regions, and others, are identical in the obtained NMOS transistors.

Step 610 comprises replacing the well arranged in the carrier substrate, conventionally N-type doped, by a P-type doped well PW, and a neutral back bias to the non-zero negative voltage −V₀. Step 610 has the effect of increasing the threshold voltage of the NMOS transistor by substantially +0.1 V.

Step 620 comprises forming the gate dielectric layer comprising a silicon oxynitride region Ndose, and forming a tensile strained channel region STRN in the semiconductor film FLMn of the NMOS transistor. Step 620 has the effect of decreasing the threshold voltage of the NMOS transistor by substantially −0.1 V.

Step 631 comprises forming a gate conductive region NG having an N-type work function, including titanium nitride and lanthanum as an additive to the titanium nitride. Step 631 has the effect of reducing the threshold voltage of the NMOS transistor by substantially −0.1 V. At the end of step 631, it has been possible to obtain the NMOS transistor having the “super low” threshold voltage SLVT.

Step 632 comprises forming a gate conductive region PG having a P-type work function, including titanium nitride and aluminum as an additive to the titanium nitride. Step 632 has the effect of increasing the threshold voltage of the NMOS transistor by substantially +0.05 V. At the end of step 632, it has been possible to obtain the NMOS transistor having the “upper median” threshold voltage RVT.

Step 641 comprises a first implantation of dopants ChII in the semiconductor film FLMn of the NMOS transistor, so as to form a channel region having a first concentration of dopant species ChII. Step 641 has the effect of increasing the threshold voltage of the NMOS transistor by substantially +0.05 V. At the end of step 641 combined with step 631, it has been possible to obtain the NMOS transistor having the “low” threshold voltage LVT. At the end of step 641 combined with step 632, it has been possible to obtain the NMOS transistor having the “high” threshold voltage HVT and/or the NMOS transistor of the SRAM cells.

Step 642 comprises a second implantation of dopants ChII2 in the semiconductor film FLMn of the NMOS transistor, so as to form a channel region having a second concentration of dopant species ChII2, which is greater than the first concentration of dopant species ChII. Step 642 has the effect of increasing the threshold voltage of the NMOS transistor by substantially +0.1 V. At the end of step 642 combined with step 631, it has been possible to obtain the NMOS transistor having the “lower median” threshold voltage iRVT. At the end of step 641 combined with step 632, it has been possible to obtain the NMOS transistor having the “ultra-high” threshold voltage uHVT and/or the NMOS transistor of the SRAM cells.

FIG. 7 illustrates steps of a method 700 for manufacturing the PMOS transistors previously described in relation to FIGS. 4 and 5. More particularly, steps 710, 720, 731, 732, 741, 742 of FIG. 7 represent the modifications made to a manufacture of a conventional PMOS transistor PMOS_lgcy to obtain the transistors TPM which are previously described in relation to FIGS. 4 and 5, that is to say the PMOS transistors configured to have the different nominal threshold voltages SLVT, LVT, iRVT, RVT, HVT in the neutral back bias NBB condition.

The conventional transistor PMOS_lgcy, considered as a starting point in step 701, is made in a P-type well arranged in the carrier substrate, includes a channel region made of silicon-germanium alloy with a germanium concentration comprised between 18% and 20% atomic percent, and has for example a threshold voltage of substantially 0.22 V. All structural characteristics of the conventional transistor PMOS_lgcy which are not modified in the method 700, such as in particular the channel length, the implantations of the P+ conduction regions, and others, are identical in the obtained PMOS transistors.

Step 710 comprise replacing the well arranged in the carrier substrate, conventionally P-type doped, by an N-type doped well NW, and a neutral back bias to the non-zero positive voltage +V₀. Step 710 has the effect of increasing the threshold voltage of the PMOS transistor by substantially +0.15 V.

Step 720 comprises forming the gate dielectric layer comprising a region of silicon oxynitride Ndose, and forming a channel region made of silicon-germanium alloy SiGe30%, with a germanium concentration greater than 25% atomic percent, for example 30%, and furthermore a compressive strain CMPR in the semiconductor film FLMp of the PMOS transistor. Step 720 has the effect of decreasing the threshold voltage of the PMOS transistor by substantially −0.15 V.

Step 731 comprises forming a gate conductive region NG having an N-type work function, including titanium nitride and lanthanum as an additive to the titanium nitride. Step 731 has the effect of increasing the threshold voltage of the PMOS transistor by substantially +0.1 V. At the end of step 731, it has been possible to obtain the PMOS transistor having the “upper median” threshold voltage RVT.

Step 732 comprises forming a gate conductive region PG having a P-type work function, including titanium nitride and aluminum as an additive to the titanium nitride. Step 732 has the effect of reducing the threshold voltage of the PMOS transistor by substantially −0.05 V. At the end of step 732, it has been possible to obtain the PMOS transistor having the “super low” threshold voltage SLVT.

Step 741 comprises a first implantation of dopants ChII in the semiconductor film FLMp of the PMOS transistor, so as to form a channel region having a first concentration of dopant species ChII. Step 741 has the effect of increasing the threshold voltage of the NMOS transistor by substantially +0.05 V. At the end of step 741 combined with step 731, it has been possible to obtain the PMOS transistor having the “high” threshold voltage HVT. At the end of step 741 combined with step 732, it has been possible to obtain the PMOS transistor having the “low” threshold voltage LVT.

Step 742 comprises a second implantation of dopants ChII2 in the semiconductor film FLMp of the PMOS transistor, so as to form a channel region having a second concentration of dopant species ChII2, which is greater than the first concentration of dopant species ChII. Step 742 has the effect of increasing the threshold voltage of the PMOS transistor by substantially +0.1 V. At the end of step 742 combined with step 732, it has been possible to obtain the PMOS transistor having the “lower median” threshold voltage iRVT.

At the same time, it will be possible to manufacture PMOS transistors with “ultra-high” threshold voltage uHVT, and PMOS transistors for SRAM memory cells, from the conventional transistor PMOS_lgcy, considered as the starting point in step 701.

At step 751, the well arranged in the P-type doped carrier substrate is not replaced, and a neutral rear bias is applied to the non-zero negative voltage −V0. Step 751 has the effect of reducing the threshold voltage of the PMOS transistor by substantially 0.08 V.

Step 752 comprises forming the gate dielectric layer comprising a silicon oxynitride region Ndose, replacing the channel region (that is to say the semiconductor film FLMp, initially made of silicon-germanium with a germanium concentration comprised between 18% and 20% atomic percent) by a channel region made of intrinsic silicon Si, and a compressive strain CMPR in the semiconductor film FLMp of the PMOS transistor. Step 720 has the effect of increasing the threshold voltage of the PMOS transistor by substantially +0.25 V.

Step 732 as described above is performed at the end of step 752, and allows obtaining the PMOS transistor adapted for SRAM memory cells.

Step 742 as described above is further performed at the end of step 732 (combined with step 752), and allows obtaining the PMOS transistor with “ultra-high” threshold voltage uHVT.

All values of increasing and decreasing the threshold voltages given above in relation to FIGS. 6 and 7 are arbitrary values nevertheless corresponding to the order of magnitude of the effects which are actually obtained in practice.

What is claimed is:

1. A semiconductor device of a silicon on insulator type including:
a NMOS transistor in and on a semiconductor film separated from a P-type doped well arranged in a carrier substrate by a buried dielectric layer,
a PMOS transistor in and on a semiconductor film separated from an N-type doped well arranged in the carrier substrate by the buried dielectric layer, and
a power supply circuit configured to generate voltages in the P-type doped well and the N-type doped well to selectively provide a neutral back bias condition, a forward back bias condition and a reverse back bias condition to the NMOS transistor and to the PMOS transistor, wherein the power supply circuit is configured to generate, for the neutral back bias condition, a first non-zero negative voltage in the P-type doped well and a first non-zero positive voltage in the N-type doped well, the NMOS and PMOS transistors being respectively configured to have nominal threshold voltages in the neutral back bias condition.

2. The device according to claim 1, wherein the power supply circuit is configured to generate, for the forward back bias condition, a voltage which is higher than the first non-zero negative voltage in the P-type doped well and a voltage which is lower than the first non-zero positive voltage in the N-type doped well.

3. The device according to claim 1, wherein the power supply circuit is configured to generate, for the reverse back bias condition, a voltage which is lower than the first non-zero negative voltage in the P-type doped well and a voltage which is higher than the first non-zero positive voltage in the N-type doped well.

4. The device according to claim 1, wherein the NMOS transistor includes a tensile strained channel region, in the respective semiconductor film, and the PMOS transistor includes a compressively strained channel region, in the respective semiconductor film.

5. The device according to claim 1, wherein the PMOS transistor includes a channel region made of silicon-germanium alloy, in the respective semiconductor film, with a germanium concentration greater than 25% atomic percent.

6. The device according to claim 1, wherein the NMOS and PMOS transistors include a gate dielectric layer located between, respectively, a gate conductive region and the semiconductor film, the gate dielectric layer comprising nitrogen so as to form a silicon oxynitride SiON layer.

7. The device according to claim 1, wherein the NMOS and PMOS transistors include a gate conductive region including titanium nitride and a titanium nitride additive selected from lanthanum and aluminum, so as to modulate a work function of a gate of the NMOS transistor and a gate of the PMOS transistor to obtain the nominal threshold voltages in the neutral back bias condition.

8. The device according to claim 1, wherein the NMOS and PMOS transistors include a respective channel region including a concentration of doping species configured to modulate a work function of the respective channel region so as to obtain the nominal threshold voltages in the neutral back bias condition.

9. The device according to claim 1, including at least one CMOS circuit provided with the NMOS transistors and the PMOS transistor, which are configured to have nominal threshold voltages in the neutral back bias condition, in at least one of the following intervals:
an interval of super low threshold voltages comprised between 0.15 V and 0.25 V in absolute values;
an interval of low threshold voltages between 0.2 V and 0.3 V in absolute values;
an interval of lower median threshold voltages between 0.25 V and 0.35 V in absolute values;
an interval of upper median threshold voltages between 0.3 V and 0.4 V in absolute values; or
an interval of high threshold voltages (HVT) between 0.35 V and 0.45 V in absolute values.

10. A method for manufacturing a semiconductor device of a silicon on insulator type comprising:
forming a NMOS transistor in and on a semiconductor film separated from a P-type doped well arranged in a carrier substrate by a buried dielectric layer,
forming a PMOS transistor in and on a semiconductor film separated from an N-type doped well arranged in the carrier substrate by the buried dielectric layer, and
forming a power supply circuit capable of generating voltages in the P-type doped well and the N-type doped well to selectively provide a neutral back bias condition, a forward back bias condition and a reverse back bias condition to the NMOS transistor and to the PMOS transistor, wherein the power supply circuit is configured to cause the neutral back bias condition by applying a first non-zero negative voltage to the P-type doped well and a first non-zero positive voltage to the N-type doped well, wherein forming the NMOS and PMOS transistors is configured to provide the NMOS and PMOS transistors with respective nominal threshold voltages in the neutral back bias condition.

11. The method according to claim 10, wherein the power supply circuit if configured to cause the forward back bias condition by applying a voltage which is higher than the first non-zero negative voltage to the P-type doped well and a voltage which is lower than the first non-zero positive voltage to the N-type doped well.

12. The method according to claim 10, wherein the power supply circuit is configured to cause the reverse back bias condition by applying a voltage which is lower than the first non-zero negative voltage to the P-type doped well and a voltage which is higher than the first non-zero positive voltage applied to the N-type doped well.

13. The method according to claim 10, wherein:
forming the NMOS transistor comprises forming a tensile strained channel region in the respective semiconductor film; and
forming the PMOS transistor includes forming a compressively strained channel region in the respective semiconductor film.

14. The method according to claim 10, wherein forming the PMOS transistor includes forming a channel region made of silicon-germanium alloy in the respective semiconductor film, with a germanium concentration greater than 25% atomic percent.

15. The method according to claim 10, wherein forming the NMOS and PMOS transistors include forming a gate dielectric layer located between, respectively, a gate conductive region and the semiconductor film, wherein the gate dielectric layer comprises nitrogen to form a silicon oxynitride SiON layer.

16. The method according to claim 10, wherein forming the NMOS and PMOS transistors include forming a gate conductive region including titanium nitride and a titanium nitride additive selected from lanthanum and aluminum, so as to modulate a work function of a gate of the NMOS transistor and a gate of the PMOS transistor to obtain the nominal threshold voltages in the neutral back bias condition.

17. The method according to claim 10, wherein forming the NMOS and PMOS transistors includes forming a respective channel region including a concentration of doping species configured modulate a work function of the respective channel region to obtain the nominal threshold voltages in the neutral back bias condition.

18. The method according claim 10, further comprising forming at least one CMOS circuit provided with the NMOS transistors and the PMOS transistor, the at least one CMOS circuit configured to provide the NMOS and PMOS transistors with nominal threshold voltages in the neutral back bias condition in at least one of the following intervals:
an interval of super low threshold voltages between 0.15 V and 0.25 V in absolute values;
an interval of low threshold voltages comprised 0.2 V and 0.3 V in absolute values;
an interval of lower median threshold voltages between 0.25 V and 0.35 V in absolute values;
an interval of upper median threshold voltages between 0.3 V and 0.4 V in absolute values; or
an interval of threshold voltages between 0.35 V and 0.45 V in absolute values.

19. A semiconductor device of a silicon on insulator type including:
a NMOS transistor in and on a semiconductor film separated from a P-type doped well arranged in a carrier substrate by a buried dielectric layer,
a PMOS transistor in and on a semiconductor film separated from an N-type doped well arranged in the carrier substrate by the buried dielectric layer, wherein:
the NMOS transistor and the PMOS transistor are configured to be in a neutral back bias condition when a first non-zero negative voltage is applied to the P-type doped well and a first non-zero positive voltage is applied to the N-type doped well, and
the NMOS and PMOS transistors are respectively configured to have nominal threshold voltages in the neutral back bias condition.

20. The device of claim 19, wherein:
the NMOS transistor and the PMOS transistor are configured to be in a forward back bias condition when a voltage higher than the first non-zero negative voltage is applied to the P-type doped well and a voltage lower than the first non-zero positive voltage is applied to the N-type doped well; and
the NMOS transistor and the PMOS transistor are configured to be in a reverse back bias condition when a voltage which is lower than the first non-zero negative voltage is applied to the P-type doped well and a voltage higher than the first non-zero positive voltage is applied to the N-type well.
